(19) United States
(12) Patent Application Publication
(10) Pub. No.: US 2013/0137212 A1
(43) Pub. Date: May 30, 2013

(54) METHOD OF MANUFACTURING AN ORGANIC THIN FILM TRANSISTOR

(71) Applicants: Samsung Electro-Mechanics Co., Ltd., Suwon (KR); Sungkyunkwan University Foundation for Coporate Collaboration, Suwon (KR)

(72) Inventors: Sang Won HA, Daejeon (KR); ll Sub Chung, Seoul (KR); Jin Hee Heo, Daejeon (KR); Kyo Hyeok Kim, Suwon (KR); Jung Min Kwon, Seongnam (KR); Kyu Hag Eum, Suwon (KR); Sang ll Yim, Anyang (KR); Chang Sup Ryu, Yongin (KR)

(73) Assignees: SUNGKYUNKWAN UNIVERSITY Foundation for Corporate Collaboration, Suwon (KR); SAMSUNG ELECTRO-MECHANICS CO., LTD., Suwon (KR)

(21) Appl. No.: 13/723,004

(22) Filed: Dec. 20, 2012

Related U.S. Application Data
(62) Division of application No. 12/975,302, filed on Dec. 21, 2010.

(30) Foreign Application Priority Data
Dec. 21, 2009 (KR) 10-2009-0128465

(51) Int. Cl. H01L 51/00

(52) U.S. Cl. CPC H01L 51/0022
USPC 438/99

(57) ABSTRACT

There is provided a method of manufacturing an organic thin film transistor. The method includes forming a plurality of barrier ribs on an insulating substrate and forming a plurality of grooves partitioned by the barrier ribs. The method further includes forming a source electrode, a drain electrode, and a gate electrode on the grooves, respectively. The method also includes forming an opening by etching the barrier ribs between the source electrode and the gate electrode and between the gate electrode and the drain electrode. The method further includes forming a gate insulating film on the opening; and forming an organic semiconductor layer on the gate insulating film.

### CROSS-REFERENCE TO RELATED APPLICATIONS

This application is a divisional of U.S. patent application Ser. No. 12/975,302, filed Dec. 21, 2010, which claims the priority of Korean Patent Application No. 10-2009-0128465 filed on Dec. 21, 2009, in the Korean Intellectual Property Office, the disclosure of all of which is incorporated herein by reference.

### BACKGROUND OF THE INVENTION

1. Field of the Invention

The present invention relates to an organic thin film transistor and a method of manufacturing the same, and more particularly, to an organic thin film transistor being capable of mass production and having excellent electrical characteristics and a method of manufacturing the same.

2. Description of the Related Art

Since polyacetylene, that is, a conjugated organic polymer that has semiconductor characteristics, has been developed, studies of transistors using an organic material have been actively made in a wide variety of fields, such as for a functional electronic device and an optical device, due to advantages of the characteristics of the organic material, that is, diverse synthesis methods, easy molding into a fiber or film shape, flexibility, conductivity, low production costs, and the like.

A silicon thin film transistor according to the prior art includes a semiconductor layer having source and drain regions doped with high-concentration impurities and a channel region formed between the two regions, a gate electrode insulated from the semiconductor layer and located in a region corresponding to the channel region, and source and drain electrodes each contacting the source and drain regions.

However, the silicon thin film transistor according to the prior art has disadvantages: it has high manufacturing costs; it is easily broken due to external impacts; and it is produced through a high-temperature process of 300□ or more and thus, a plastic substrate or the like is not able to be used therefor.

In particular, a flat panel display apparatus, such as a liquid crystal display apparatus, an organic light emitting display apparatus or the like, uses a thin film transistor as a switching device that controls the operations of each pixel and a driving device of each pixel. There has been an increased attempt to use a substrate made of plastics and the like other than the existing glass, in order to meet the recent trends that the flat panel display apparatus has become larger and slimmer, and the flexible characteristics thereof. However, when the plastic substrate is used, a low-temperature process should be performed, rather than the high-temperature process as described above. Therefore, it has been difficult to use the silicon thin film transistor according to the prior art.

On the contrary, when an organic film is used as the semiconductor layer of the thin film transistor, such problems can be solved. Therefore, recently, studies for an organic thin film transistor that uses the organic film as the semiconductor layer have been actively made.

Meanwhile, there has been an attempt to form each layer of the organic thin film transistor using various printing methods, for example, an inkjet printing method, in order to minimize the loss of material and reduce manufacturing costs and time expended thereupon.

The inkjet printing process is made in such a manner that an ink composition is manufactured by mixing an organic material or conductive particles forming a layer intended to be formed with a solvent and then the ink composition is dropped on a predetermined position. When the layer including the organic material or the conductive particles is formed by the inkjet printing process, the ink composition may be spread to the periphery rather than the desired position at the time of dropping the ink composition, causing a difficulty in forming a layer having a fine pattern.

### SUMMARY OF THE INVENTION

An aspect of the present invention provides an organic thin film transistor being capable of mass production and having excellent electrical characteristics and a method of manufacturing the same.

According to an aspect of the present invention, there is provided an organic thin film transistor including: an insulating substrate on which a plurality of barrier ribs and a plurality of grooves partitioned by the barrier ribs are formed; source and drain electrodes each formed on the grooves spaced apart from each other among the plurality of grooves; a gate electrode formed on the groove between the source and drain electrodes; an opening formed by etching the barrier ribs between the source electrode and the gate electrode and between the gate electrode and the drain electrode; a gate insulating film formed on the opening; and an organic semiconductor layer formed on the gate insulating film.

The plurality of grooves may have different bottom heights and the groove on which the gate electrode is formed may have a bottom height lower than those of the grooves on which the source and drain electrodes are formed.

The gate electrode may have a height lower than those of the source and drain electrodes.

The gate insulating film may be formed up to the lower portions of the source and drain electrodes.

The organic thin film transistor may further include a self-assembled monolayer formed between the gate insulating film and the organic semiconductor layer.

The organic thin film transistor may further include a protective layer formed on the organic semiconductor layer.

According to another aspect of the present invention, there is provided a method of manufacturing an organic thin film transistor, including: forming a plurality of barrier ribs on an insulating substrate and forming a plurality of grooves partitioned by the barrier ribs; forming a source electrode, a drain electrode, and a gate electrode on the grooves, respectively; forming an opening by etching the barrier ribs between the source electrode and the gate electrode and between the gate electrode and the drain electrode; forming a gate insulating film on the opening; and forming an organic semiconductor layer on the gate insulating film.

The forming of the plurality of barrier ribs may be performed by an imprint method.

The plurality of grooves may have different bottom heights and the groove on which the gate electrode is to be formed may have a bottom height lower than those of the grooves on which the source and drain electrodes are to be formed.

The forming of the source electrode, the drain electrode, and the gate electrode may be performed by an inkjet printing method.

The gate electrode may have a height lower than those of the source and drain electrodes.

The forming of the opening may be performed by dropping an etching solution on the barrier ribs through an inkjet printing unit.

The opening may be formed up to the lower portions of the source and drain electrodes.

The forming of the gate insulating film may be performed by the inkjet printing method.

The method of manufacturing the organic thin film transistor may further include forming a self-assembled monolayer on the gate insulating film by the inkjet printing method.

The method of manufacturing the organic thin film transistor may further include forming a protective layer on the organic semiconductor layer by the inkjet printing method.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view showing an organic thin film transistor according to an exemplary embodiment of the present invention; and

FIGS. 2A through 2H are cross-sectional views for each process explaining a method of manufacturing an organic thin film transistor according to an exemplary embodiment of the present invention.

### DETAILED DESCRIPTION OF THE PREFERRED EMBODIMENT

Exemplary embodiments of the present invention will now be described in detail with reference to the accompanying drawings. The exemplary embodiments of the present invention may be modified in many different forms and the scope of the invention should not be limited to the embodiments set forth herein. Rather, these embodiments are provided so that this disclosure will be thorough and complete, and will fully convey the concept of the invention to those skilled in the art. In the drawings, the shapes and dimensions may be exaggerated for clarity, and the same reference numerals will be used throughout to designate the same or like components.

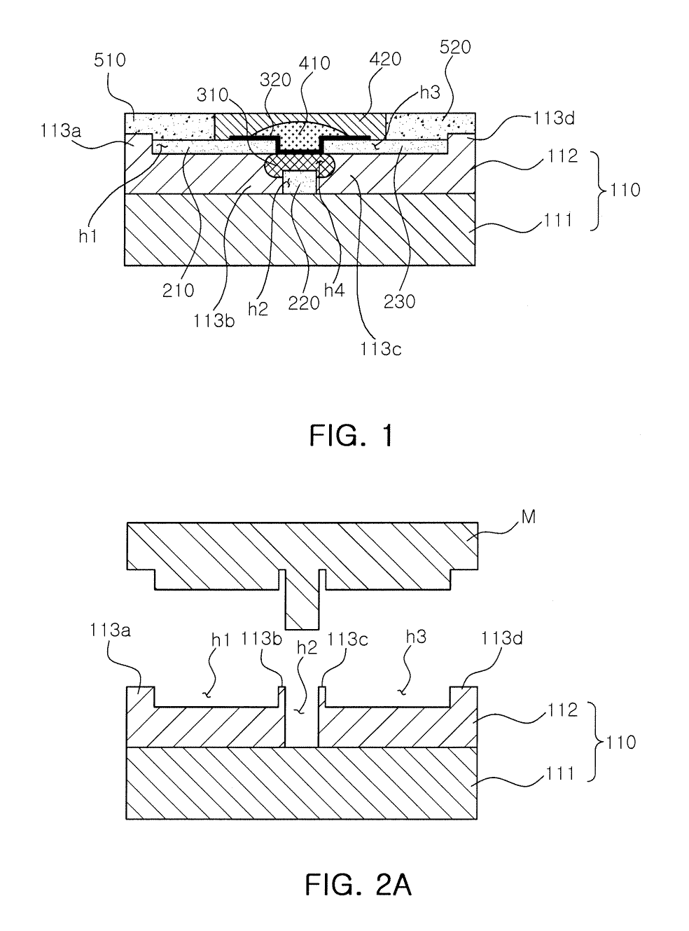

FIG. 1 is a schematic cross-sectional view showing an organic thin film transistor according to an exemplary embodiment of the present invention.

Referring to FIG. 1, an organic thin film transistor according to an exemplary embodiment of the present invention includes an insulating substrate 110 on which a plurality of barrier ribs 113a, 113b, 113c, and 113d and a plurality of grooves h1, h2, and h3 partitioned by the barrier ribs are formed. The insulating substrate 110 may be an inorganic substrate such as silicon or glass or a flexible plastic substrate.

The flexible plastic substrate is not limited thereto; however, it may also use polyethyleneterepthalate (PET), polyethylenen napthalate (PEN), polycarbonate (PC), polyimide, or the like.

According to the present invention, a semiconductor layer is made of an organic semiconductor material so that a low-temperature process of 200□ or less can be performed, thereby making it possible to use the flexible plastic substrate. Therefore, a thin film transistor having flexible characteristics can be manufactured.

A source electrode 210 and a drain electrode 230 each are formed on the first groove h1 and the third groove h3 spaced apart from each other, among the plurality of grooves.

Also, a gate electrode 220 is formed on the second groove h2 between the first groove h1 and the third groove h3.

The plurality of grooves h1, h2, and h3 may have different bottom heights. For example, the second groove h2 on which the gate electrode is to be formed may have a bottom height higher or lower than those of the first and third grooves h1 and h3.

The gate electrode 220 may also have a height lower than those of the source/drain electrodes 210 and 230.

As shown, when the second groove h2 on which the gate electrode is formed has the bottom height lower than those of the first and the third grooves h1 and h3, a bottom-gate type thin film transistor is provided.

However, the present embodiment is not limited thereto, and when the second groove h2 on which the gate electrode is formed has a bottom height higher than those of the first and the third grooves h1 and h3, a top-gate type thin film transistor is provided.

Portions of the barrier ribs 113b and 113c between the source electrode 210 and the gate electrode 220 and between the gate electrode 220 and the drain electrode 230 are etched, thereby forming an opening h4. A gate insulating film 310 is formed on the opening h4.

The opening h4 is formed by removing portions of the barrier ribs 113b and 113c by performing chemical etching, wherein the shape thereof may be determined by the concentration, dropping time, or the like of an etching solution. The opening h4 is formed up to the lower portions of the source/drain electrodes 210 and 230 so that the gate insulating film 310 can be formed up to the lower portions of the source/drain electrodes 210 and 230.

The thickness of the gate insulating film 310 is determined in consideration of the insulating characteristics of the thin film transistor and the characteristics of the gate electrode.

The gate insulating film may be formed using various materials such as an inorganic material, an organic material, or the like. As for the gate insulating film, for example, it may be poly vinyl pyrrolidone, polystyrene, styrene-butadiene copolymer, polyvinyl phenol, poly phenols, or the like.

An organic semiconductor layer 410 is formed on the gate insulating film 310.

The organic semiconductor layer 410 may be made of various materials, however, it is not limited thereto. As for the organic semiconductor layer 410, for example, it may be pentacene, tetracene, anthracene, naphthalene, alpha-6-thiophene, alpha-5-thiophene, alpha-4-thiophene, perylene and its derivatives, rubrene and its derivatives, coronene and its derivatives, perylene tetracarboxylic diimide and its derivatives, perylene tetracarboxylic dianhydride and its derivatives, polythiophen and its derivatives, poly-p-phenylenevinylene and its derivatives, poly-paraphenylene and its derivatives, polyfluorene and its derivatives, polythiophenevinylene and its derivatives, polythiophene-heterocyclic aromatic copolymer and its derivatives, phthalocyanine that does or does not include a metal and its derivatives, pyromelitic dianhydride and its derivatives, pyromelitic diimide and its derivatives, or the like.

A self-assembled monolayer (SAM) 320 may be formed between the gate insulating film 310 and the organic semiconductor layer 410.

The self-assembled monolayer may include octyltrichlorosilane (OTS). The octyltrichlorosilane reduces a surface energy of the gate insulating film so that a large amount of a solution that forms the organic semiconductor layer to be subsequently formed is formed on the same area, thereby making it possible to form a thick organic semiconductor layer.

When the thick organic semiconductor layer is formed, it prevents a channel part of the organic semiconductor layer from being damaged due to oxygen, water or the like in the air, thereby making it possible to prevent the characteristics of the thin film transistor from being degraded.

Further, a protective layer 420 may be formed on the organic semiconductor layer 410. The protective layer may be made of an organic insulating material or an inorganic insulating material.

A source electrode contact pad 510 and a drain electrode contact pad 520 contacting the source and drain electrodes may also be formed on the source and drain electrodes 210 and 230.

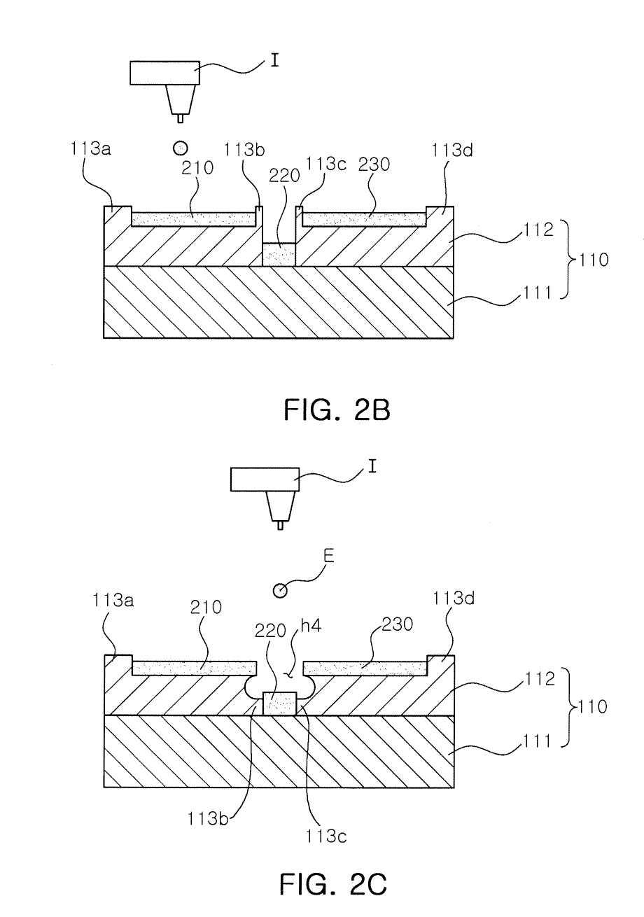

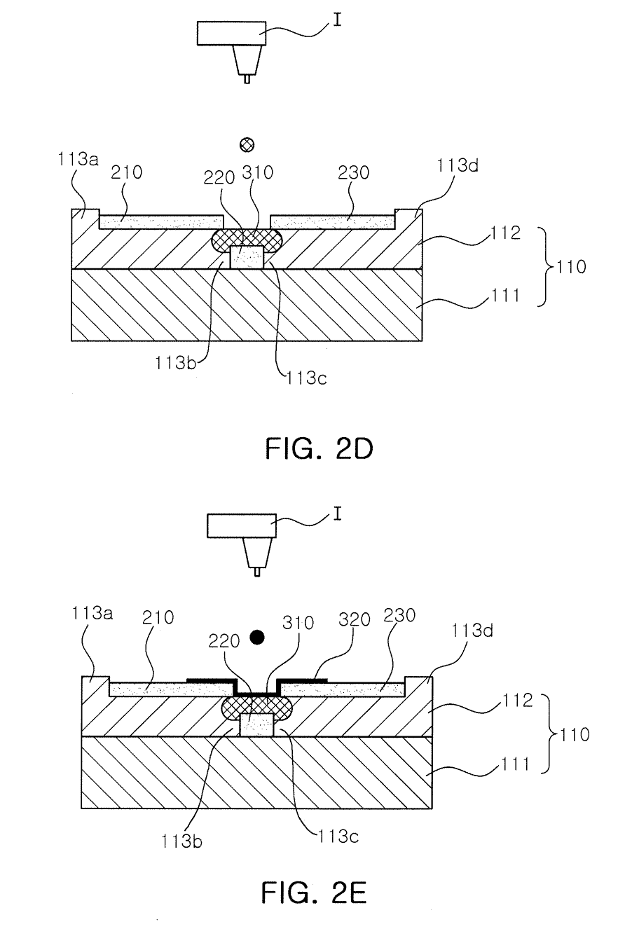

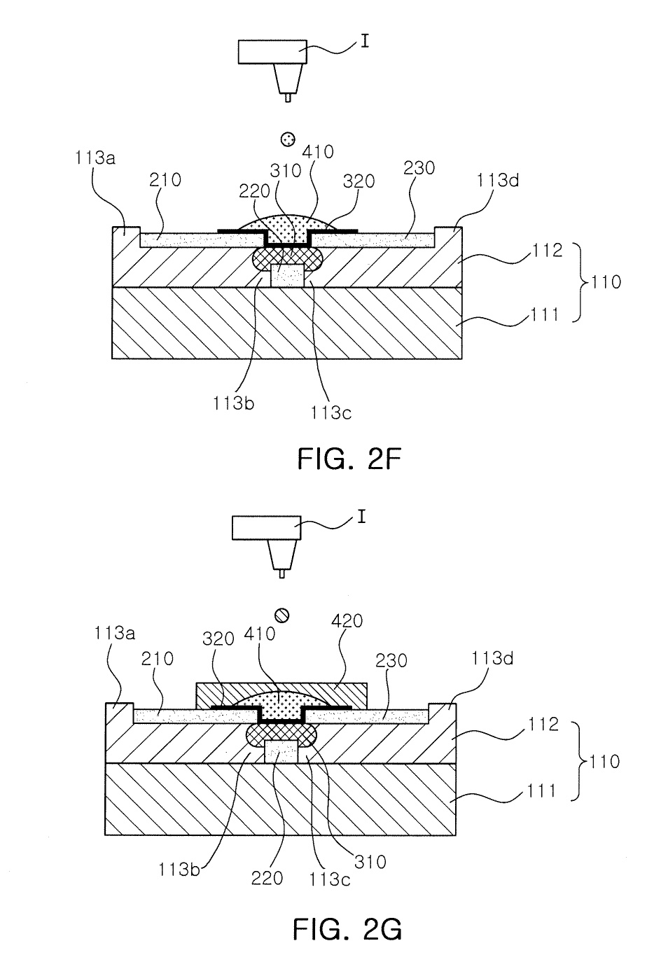

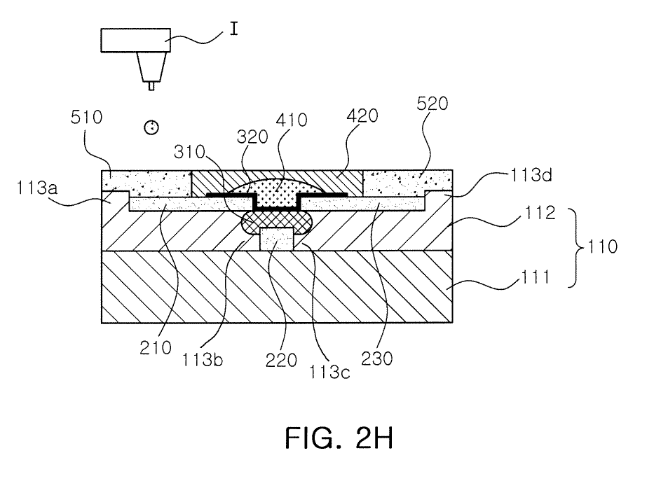

Hereinafter, a method for manufacturing an organic thin film transistor according to the present invention will be described with reference to FIGS. 2A through 2H.

FIGS. 2A through 2H are cross-sectional views for each process explaining a method of manufacturing an organic thin film transistor according to an exemplary embodiment of the present invention.

First, referring to FIG. 2A, an insulating substrate 110 on which an organic thin film transistor is to be manufactured is provided. The insulating substrate 110 may be an inorganic substrate such as silicon or glass or a flexible plastic substrate.

Then, a plurality of barrier ribs 113a, 113b, 113c, and 113d are formed on the insulating substrate 110. When the insulating substrate is an inorganic substrate 111, a curable resin layer 112 may be formed on the inorganic substrate 111 and then barrier ribs 113a, 113b, 113c, and 113d may be formed on the curable resin layer.

When the insulating substrate is a flexible plastic substrate, the barrier ribs may be directly formed on the insulating substrate. Alternatively, the curable resin layer may be formed on the insulating substrate and then the barrier ribs may be formed on the curable resin layer.

The curable resin is not limited thereto, however, it may use unsaturated polyester, epoxy, polyester methacrylate, polyvinyl alcohol, or the like.

A method of forming a plurality of barrier ribs on the insulating substrate 110 is not specifically limited, however, it may use an imprint method, a laser patterning method, a photolithography method, an etching method, and the like.

For example, as shown in FIG. 2A, the curable resin layer 112 having a predetermined thickness is formed on the insulating substrate and then the curable resin layer 112 is compressed using a stamp M having relief and intaglio patterns, thereby forming the barrier ribs 113a, 113b, 113c, and 113d corresponding to the relief and intaglio patterns of the stamp. A plurality of grooves h1, h2, and h3 are formed on the insulating substrate by the barrier ribs.

At this time, the intervals between the barrier ribs and the shape and size of the grooves formed by the barrier ribs may be determined by controlling the relief and intaglio patterns of the stamp.

The plurality of grooves h1, h2, and h3 may have different bottom heights. For example, the second groove h2 on which a gate electrode is to be formed may be formed to have a bottom height higher or lower than those of the first and third grooves h1 and h3.

Then, as shown in FIG. 2B, a source electrode, a gate electrode, and a drain electrode are formed on the plurality of grooves on the insulating substrate 110, respectively.

The electrodes may use a metal material such as aluminum, tungsten, chrome, and the like, or a conductive polymer material such as polyethylenedioxythiophene/polystyrene Sulfonate (PEDOT/PSS), polyaniline, or the like.

The electrodes may be formed by an inkjet printing method, wherein the inkjet printing process may be made in such a manner that an ink composition is manufactured by mixing a metal material or a conductive polymer material with a solvent and then the ink composition is dropped on the grooves.

For example, the source electrode 210 is formed on the first groove h1, the gate electrode 220 is formed on the second groove h2, and the drain electrode 230 is formed on the third groove h3. At this time, the gate electrode 220 may have a height lower than those of the source/drain electrodes 210 and 230.

In the exemplary embodiment of the present invention, the grooves on which each electrode is formed are partitioned by the barrier ribs so that the inkjet composition is not spread to the periphery rather than the desired position of the ink composition, thereby making it possible to form a fine electrode pattern. Further, the grooves on which the source/drain electrodes and the gate electrode are to be formed are simultaneously formed from the beginning, thereby making it possible to solve a parasitic capacitance phenomenon and a layer alignment due to gate overlapping.

Then. as shown in FIG. 2C, an opening h4 is formed by etching portions of the barrier ribs 113b and 113c between the source electrode and the gate electrode and between the gate electrode and the drain electrode.

The etching is not specifically limited, however, it may be formed by performing chemical etching. More specifically, an etching solution is dropped on the barrier ribs through an inkjet printing unit I, thereby making it possible to etch the barrier ribs.

The shape of the opening h4 may be determined by the concentration, dropping time, or the like of the etching solution. At this time, the opening h4 may be formed up to the lower portions of the source and drain electrodes 210 and 230.

Then, as shown in FIG. 2D, a gate insulating film 310 is formed on the opening. The thickness of the gate insulating film 310 is determined in consideration of the insulating characteristics of a thin film transistor and the characteristics of the gate electrode. The gate insulating film 310 may be formed up to the lower portions of the source and drain electrodes 210 and 230.

The gate insulating film 310 may be formed using various materials such as an inorganic material, an organic material, or the like. As for the gate insulating film, for example, it may be poly vinyl pyrrolidone, polystyrene, styrene-butadiene copolymer, polyvinyl phenol, poly phenols, and the like.

The gate insulating film 310 may be formed by an inkjet printing method, wherein the inkjet printing process may be made in such a manner that an ink composition is manufactured by mixing the gate insulating film material with a solvent and then the ink composition is dropped on the opening h4 from the inkjet printing unit I.

Then, as shown in FIG. 2E, a self-assembled monolayer (SAM) 320 is formed on the gate insulating film. The forming of the self-assembled monolayer 320 is not indispensable, and an organic semiconductor layer 410 may also formed directly on the gate insulating film 310.

The self-assembled monolayer 320 may include octyltrichlorosilane (OTS). The octyltrichlorosilane reduces a surface energy of the gate insulating film so that more amount of a solution that forms the organic semiconductor layer to be subsequently formed is formed on the same area, thereby making it possible to form a thick organic semiconductor layer.

When the thick organic semiconductor layer is formed, it prevents a channel part of the organic semiconductor layer from being damaged due to oxygen, water or the like in the air, thereby making it possible to prevent the characteristics of the thin film transistor from being degraded.

The self-assembled monolayer 320 may be formed by an inkjet printing method, wherein the inkjet printing process may be made in such a manner that an ink composition is manufactured by mixing the self-assembled monolayer material with a solvent and then the ink composition is dropped on the gate insulating film 310 from the inkjet printing unit I.

Then, as shown in FIG. 2F, the organic semiconductor layer 410 is formed on the self-assembled monolayer 320. When the self-assembled monolayer 320 is not formed, the organic semiconductor layer 410 may also formed directly on the gate insulating film 310.

The organic semiconductor layer 410 may be made of various materials, however, it is not limited thereto. As for the organic semiconductor layer 410, for example, it may be pentacene, tetracene, anthracene, naphthalene, alpha-6-thiophene, alpha-5-thiophene, alpha-4-thiophene, perylene and its derivatives, rubrene and its derivatives, coronene and its derivatives, perylene tetracarboxylic diimide and its derivatives, perylene tetracarboxylic dianhydride and its derivatives, polythiophen and its derivatives, poly-p-phenylenevinylene and its derivatives, poly-paraphenylene and its derivatives, polyfluorene and its derivatives, polythiophenevinylene and its derivatives, polythiophene-heterocyclic aromatic copolymer and its derivatives, phthalocyanine that does or does not include a metal and its derivatives, pyromelitic dianhydride and its derivatives, pyromelitic diimide and its derivatives, and the like.

The organic semiconductor layer 410 may be formed by an inkjet printing method, wherein the inkjet printing process may be made in such a manner that an ink composition is manufactured by mixing the organic semiconductor layer material with a solvent and then the ink composition is dropped on the self-assembled monolayer 320 from the inkjet printing unit

Further, as shown in FIG. 2G, a protective layer 420 may be formed on the organic semiconductor layer 410.

The protective layer 420 may be formed by an inkjet printing method, wherein the inkjet printing process may be made in such a manner that an ink composition is manufactured by mixing the protective layer material with a solvent and then the ink composition is dropped on the organic semiconductor layer 410 from the inkjet printing unit

Then, as shown in FIG. 2H, a source electrode contact pad 510 and a drain electrode contact pad 520 contacting the source and drain electrodes may be formed on the source and drain electrodes 210 and 230.

The source electrode contact pad 510 and the drain electrode contact pad 520 may be formed by an inkjet printing method, wherein the inkjet printing process may be made in such a manner that an ink composition is manufactured by mixing the contact pad material with a solvent and then the ink composition is dropped on the source and drain electrodes 210 and 230 from the inkjet printing unit I.

As set forth above, according to exemplary embodiments of the present invention, the grooves on which the source electrode, the drain electrode, and the gate electrode are formed are partitioned by the barrier ribs so that the inkjet composition is not spread to the periphery rather than the desired position of the ink composition, thereby making it possible to form a fine electrode pattern.

The grooves on which the source/drain electrodes and the gate electrode are to be formed are simultaneously formed from the beginning so that a parasitic capacitance due to gate overlapping is reduced, thereby having excellent electrical characteristics of the organic thin film transistor.

Further, a process for subsequently aligning the gate is not required and each layer is formed by inkjet printing method, thereby making it possible to achieve mass production.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing an organic thin film transistor, comprising:
forming a plurality of barrier ribs on an insulating substrate and forming a plurality of grooves partitioned by the barrier ribs;
forming a source electrode, a drain electrode, and a gate electrode on the grooves, respectively;
forming an opening by etching the barrier ribs between the source electrode and the gate electrode and between the gate electrode and the drain electrode;
forming a gate insulating film on the opening; and
forming an organic semiconductor layer on the gate insulating film.

2. The method of manufacturing an organic thin film transistor of claim 1, wherein the forming of the plurality of barrier ribs is performed by an imprint method.

3. The method of manufacturing an organic thin film transistor of claim 1, wherein the plurality of grooves have different bottom heights.

4. The method of manufacturing an organic thin film transistor of claim 1, wherein the groove on which the gate electrode is to be formed has a bottom height lower than those of the grooves on which the source and drain electrodes are to be formed.

5. The method of manufacturing an organic thin film transistor of claim 1, wherein the forming of the source electrode, the drain electrode, and the gate electrode is performed by an inkjet printing method.

6. The method of manufacturing an organic thin film transistor of claim 1, wherein the gate electrode has a height lower than those of the source and drain electrodes.

7. The method of manufacturing an organic thin film transistor of claim 1, wherein the forming of the opening is performed by dropping an etching solution on the barrier ribs through an inkjet printing unit.

8. The method of manufacturing an organic thin film transistor of claim 1, wherein the opening is formed up to the lower portions of the source and drain electrodes.

9. The method of manufacturing an organic thin film transistor of claim 1, wherein the forming of the gate insulating film is performed by the inkjet printing method.

10. The method of manufacturing an organic thin film transistor of claim 1, further comprising forming a self-assembled monolayer on the gate insulating film by the inkjet printing method.

11. The method of manufacturing an organic thin film transistor of claim 1, further comprising forming a protective layer on the organic semiconductor layer by the inkjet printing method.
